(19) United States
(12) Patent Application Publication
(10) Pub. No.: US 2025/0105830 A1
(43) Pub. Date: Mar. 27, 2025

(54) PATTERN-AWARE ENHANCED CROSSTALK CANCELLATION (PEXTC) SCHEME

(71) Applicants: Ranjul Balakrishnan, Bangalore (IN); Sagar Dubey, Bangalore (IN); Taner Sumesaglam, Folsom, CA (US)

(72) Inventors: Ranjul Balakrishnan, Bangalore (IN); Sagar Dubey, Bangalore (IN); Taner Sumesaglam, Folsom, CA (US)

(21) Appl. No.: 18/372,247

(22) Filed: Sep. 25, 2023

(51) Int. Cl. H03K 5/1252; H03K 19/20

(52) U.S. Cl. CPC H03K 5/1252; H03K 19/20

(57) ABSTRACT

An apparatus includes a signal pattern sensing circuit and a cross-talk cancellation (XTC) circuit. The signal pattern sensing circuit includes a plurality of logical gates. The signal pattern sensing circuit receives a first signal and a second signal. The signal pattern sensing circuit generates an enable signal at an output of one of the plurality of logical gates based on a switching pattern of the first signal and the second signal. The XTC circuit includes a buffer coupled to a capacitor. The capacitor receives the second signal via the buffer. The XTC circuit dynamically couples an output of the capacitor to a communication channel of the first signal based on the enable signal.

### BACKGROUND

The performance of the high-speed parallel buses is limited by channel cross-talk interference. Routing the dense parallel bus can be challenging when the available board/package real estate is limited. While enabling low-cost packages and platforms, channel design is compromised for a higher cross-talk in the transmission lines due to limited stack options. To tackle the channel cross-talks and improve the interface performance, cross-talk cancellation (XTC) techniques can be used. However, existing XTC techniques are associated with limited solution space and increased power dissipation.

### BRIEF DESCRIPTION OF THE DRAWINGS

In the drawings, like numerals may describe the same or similar components or features in different views. Like numerals having different letter suffixes may represent different instances of similar components. Some embodiments are illustrated by way of example, and not limitation, in the figures of the accompanying drawings in which:

FIG. 1 illustrates a high-level block diagram of a transmit (Tx) side XTC architecture, in accordance with some embodiments;

FIG. 2 illustrates a high-level block diagram of a Tx side XTC architecture using a pattern-aware (PAW) logic, in accordance with some embodiments;

FIG. 3 illustrates a high-level block diagram of a Tx side pattern-aware enhanced XTC (PeXTC) architecture, in accordance with some embodiments;

FIG. 4 illustrates a truth table that can be used by the PeXTC architecture of FIG. 3, in accordance with some embodiments;

FIG. 5 illustrates graphs showing improvement in margin with XTC gain in a regular XTC versus a PeXTC for a memory channel, in accordance with some embodiments;

FIG. 6 illustrates a table showing improvement with a regular XTC and PeXTC for a memory channel, in accordance with some embodiments;

FIG. 7 illustrates a table showing improvement with a regular XTC and PeXTC for another memory channel, in accordance with some embodiments;

FIG. 8 illustrates graphs of victim line modulation due to cross-talk aggressor pattern dependency, in accordance with some embodiments;

FIG. 9 illustrates a graph of victim pattern with aggressor impact (e.g., high-side slice from FIG. 8), in accordance with some embodiments;

FIG. 10 illustrates a table with XTC gain delay sweep (e.g., current XTC techniques versus disclosed PeXTC techniques), in accordance with some embodiments;

FIG. 11 illustrates a table with a summary of best-case margins comparison and circuit effectiveness, in accordance with some embodiments;

FIG. 12 illustrates a graph of two sequential bursts of random even mode and odd mode victim-aggressor patterns, in accordance with some embodiments;

FIG. 13 illustrates a table with regular XTC circuit parameter sweeps and impact with odd mode and even mode aggression, in accordance with some embodiments;

FIG. 14 is a flow diagram of an example method for cross-talk cancellation (XTC), in accordance with some embodiments; and

FIG. 15 illustrates a block diagram of an example machine upon which any one or more of the operations/techniques (e.g., methodologies) discussed herein may perform.

### DETAILED DESCRIPTION

The following detailed description refers to the accompanying drawings. The same reference numbers may be used in different drawings to identify the same or similar elements. In the following description, for purposes of explanation and not limitation, specific details are set forth, such as particular structures, architectures, interfaces, techniques, etc., to provide a thorough understanding of the various aspects of various embodiments. However, it will be apparent to those skilled in the art having the benefit of the present disclosure that the multiple aspects of the various embodiments may be practiced in other examples that depart from these specific details. In certain instances, descriptions of well-known devices, circuits, and methods are omitted so as not to obscure the description of the various embodiments with unnecessary detail.

The following description and the drawings sufficiently illustrate specific embodiments to enable those skilled in the art to practice them. Other embodiments may incorporate structural, logical, electrical, process, and other changes. Portions and features of some embodiments may be included in or substituted for those of other embodiments. Embodiments outlined in the claims encompass all available equivalents of those claims.

As used herein, the term “chip” (or die) refers to a piece of a material, such as a semiconductor material, that includes a circuit, such as an integrated circuit or a part of an integrated circuit. The term “memory IP” indicates memory intellectual property. The terms “memory IP,” “memory device,” “memory chip,” and “memory” are interchangeable.

The term “a processor” configured to carry out specific operations includes both a single processor configured to carry out all of the functions (e.g., operations or methods disclosed herein) as well as multiple processors individually configured to carry out some or all of the operations (which may overlap) such that the combination of processors carry out all of the operations.

As used herein, the term “odd mode pattern” indicates that two signals (e.g., a first signal (also referred to as a victim signal) and a second signal (also referred to as an aggressor signal)) switch periods in different directions at a given time. As used herein, the term “even mode pattern” indicates that the two signals switch periods in the same direction at a given time.

In some aspects, in order to tackle the channel cross-talk and improve the interface performance, passive XTC techniques and active cross-talk cancellation circuits can be utilized. Passive cross-talk cancellation provides a fixed solution that needs careful design and can result in a limited solution space. Passive XTC schemes (e.g., stubby transmission lines, coupled via schemes, fuzzy via schemes, etc.) are fixed solutions that are not scalable.

Active XTC provides a scalable solution with the expense of additional power dissipation in the circuit and with an overload associated with circuit addition. Additionally, active XTC circuits (implementable at the transmitter side or receiver side) may have limitations on the power and performance.

Present active and passive XTC techniques are associated with the following drawbacks:

(a) Both passive and presently implemented active XTC circuits are limited/constrained by a uniform XTC scheme across all the aggressor patterns as detailed below (whose drawbacks are overcome by the disclosed PeXTC techniques).

(b) The cross-talk from a specific pattern is destructive, but the opposite of that pattern is constructive. If a channel is inductively coupled, even mode patterns are destructive, and odd mode patterns are constructive.

(c) Presently, regular XTC is uniformly applied irrespective of the aggressor pattern and is targeted to compensate for the cross talk from a destructive pattern.

(d) The constructive pattern gain is nullified when regular XTC is applied uniformly without pattern awareness.

(e) Regular XTC implementation without pattern awareness limits the circuit optimization for destructive patterns as a reduction in the constructive pattern becomes limiter. Regular XTC effectiveness is significantly compromised due to this feature.

(f) Regular XTC is always on and constantly consuming power.

The disclosed pattern-aware enhanced cross-talk cancellation (PeXTC) techniques overcome the limitations of the regular crosstalk cancellation (XTC) circuits to improve the effectiveness of active cross-talk cancellation circuits. The proposed scheme can save approximately 40 to 50% of the power dissipated with the current active cancellation circuit.

According to the disclosed PeXTC techniques, the XTC circuit will be turned ON and OFF dynamically based on the aggressor signal pattern relative to the victim signal pattern. The disclosed PeXTC scheme significantly enhances the XTC effectiveness of suppressing the noise, boosting the signal, and improving the SNR.

Assuming a random pattern, the probability of turning OFF the XTC could be greater than 80% of the aggressor pattern, which can save up to 80% of XTC circuit power burn as well. The disclosed PeXTC techniques result in higher performance of high-speed interfaces (e.g., DDRx, LPx, and GDDRx technologies) and can be applied on single-ended switching and dense parallel buses.

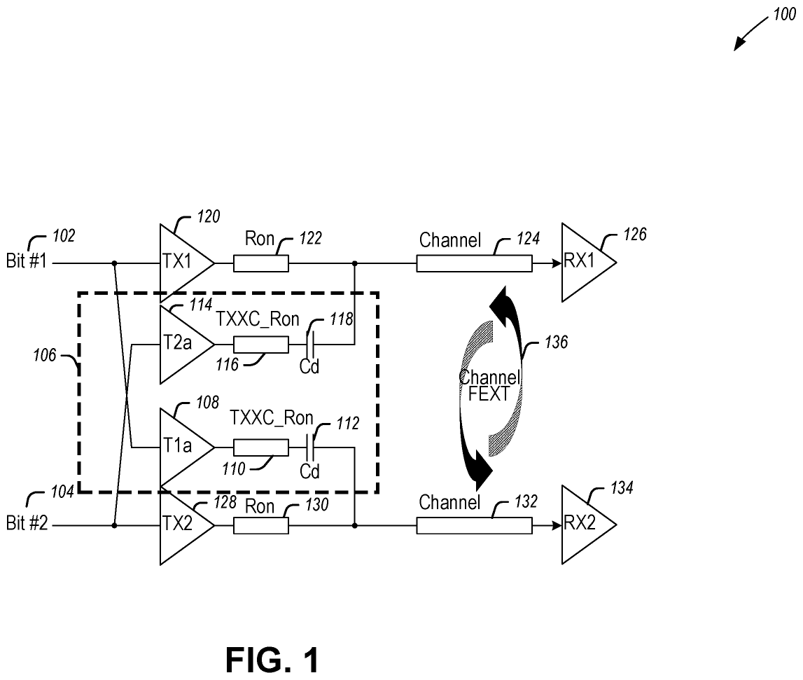

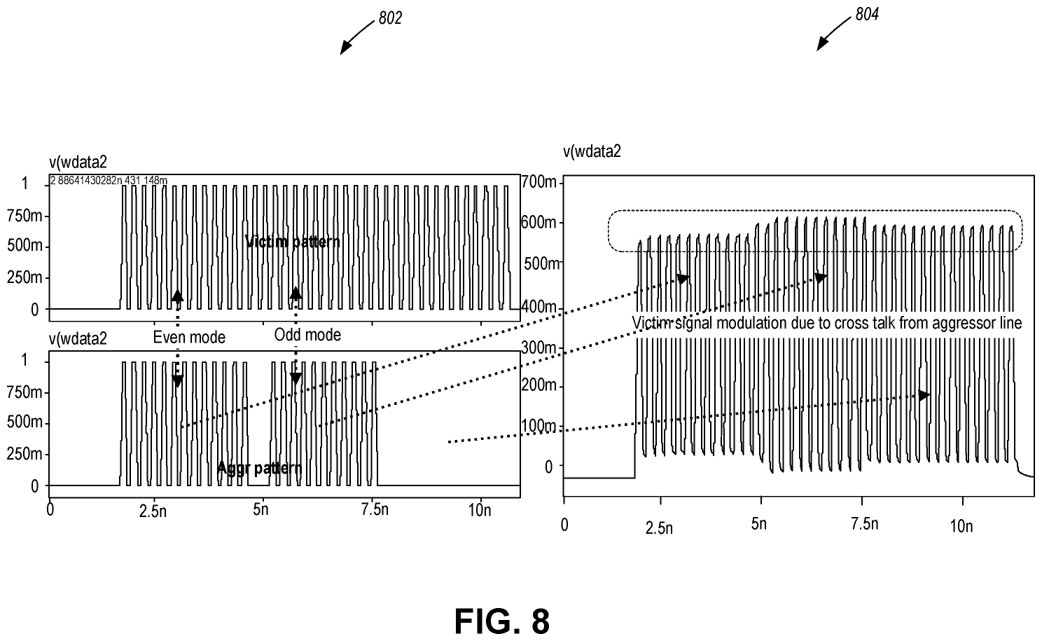

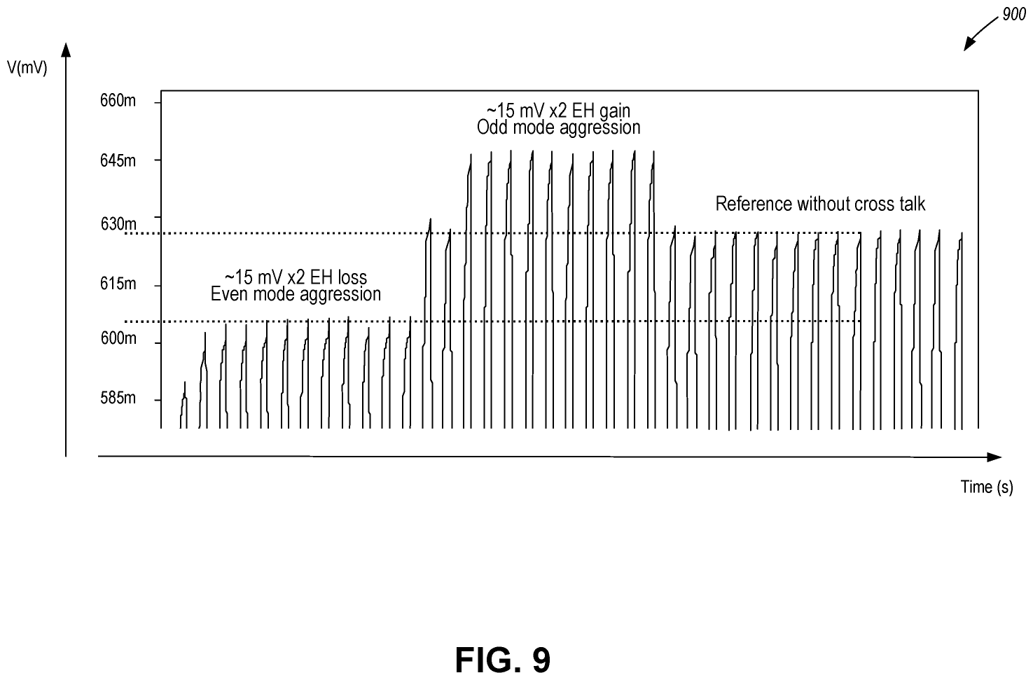

Crosstalk has been one of the significant limiters in dense parallel buses (e.g., memory interfaces) while enabling higher data rates. Crosstalk from the aggressor bits could be either destructive or constructive. A destructive crosstalk will reduce the victim signal margin, while a constructive crosstalk will improve the victim signal margin. This is further shown in FIG. 8 and FIG. 9 below. FIGS. 1-3 illustrate example XTC architectures that may use the disclosed techniques.

FIG. 1 illustrates a high-level block diagram of a transmit (Tx) side XTC architecture, in accordance with some embodiments. Referring to FIG. 1, the XTC architecture 100 includes a transmit buffer 120 (also referred to as a Tx buffer) receiving a first signal 120, a channel resistance 122, a communication channel 124 for the first signal, and a receive buffer 126 (also referred to as Rx buffer).

The XTC architecture 100 further includes a Tx buffer 128 receiving a second signal 104, a channel resistance 130, a communication channel 132 for the second signal, and an Rx buffer 134.

XTC architecture 100 may be associated with far-end cross-talk (FEXT) 136 between communication channels 124 and 132. In some aspects, an active XTC circuit 106 can be used to mitigate the FEXT 136.

In some aspects, the active XTC circuit 106 includes a buffer 114, channel resistance 116, and a capacitor 118, coupling the second signal 104 with the communication channel 124 of the first signal 102. The active XTC circuit 106 further includes a buffer 108, channel resistance 110, and a capacitor 112, coupling the first signal 102 with the communication channel 132 of the second signal 104.

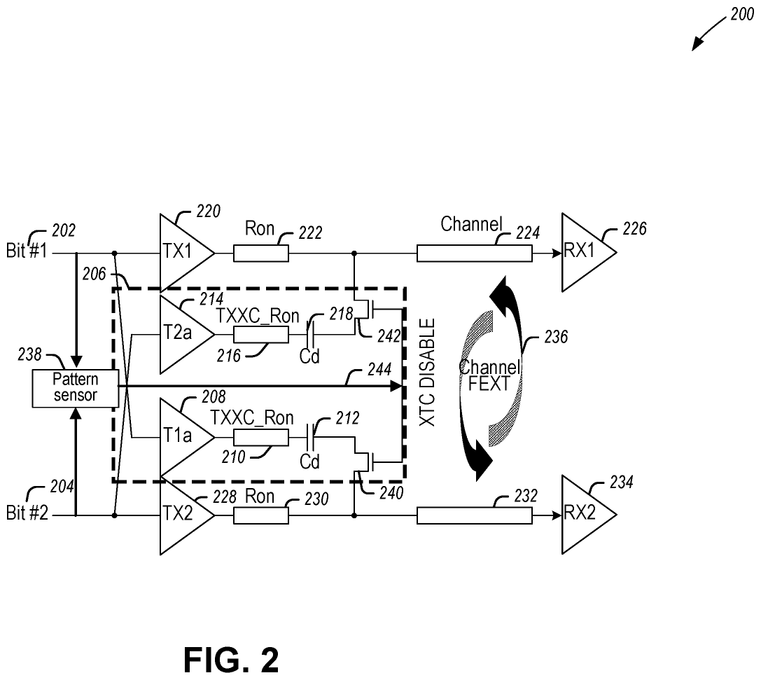

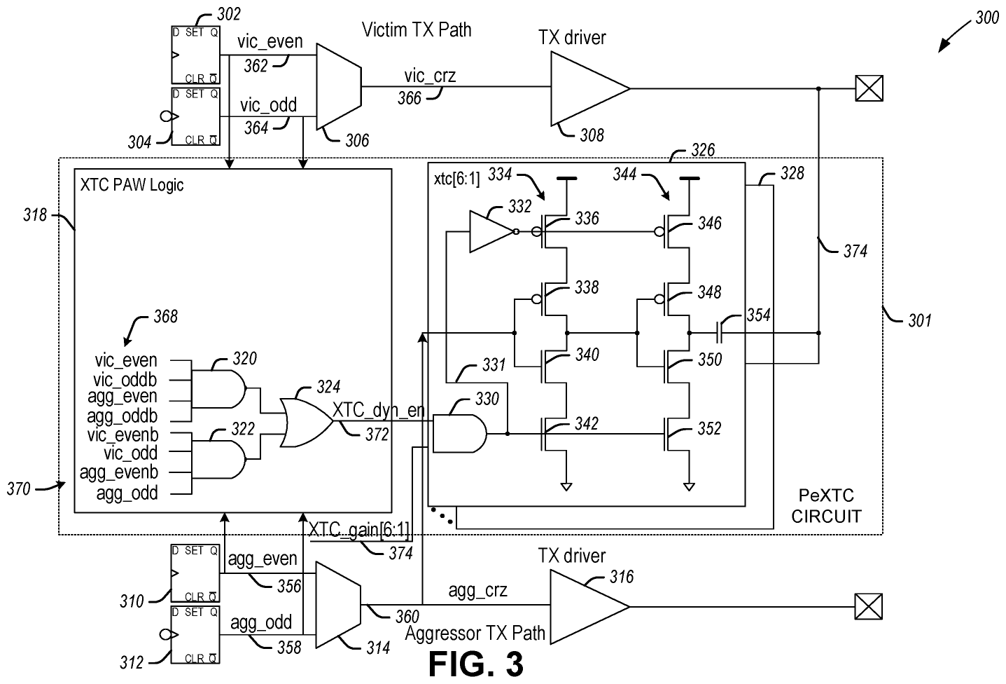

In some embodiments, XTC circuits (e.g., the active XTC circuit 106) can be configured as a PeXTC circuit using the disclosed techniques (e.g., as discussed in connection with FIG. 2 and FIG. 3).

FIG. 2 illustrates a high-level block diagram of a Tx side XTC architecture 200 using a PAW logic, in accordance with some embodiments. Referring to FIG. 2, the XTC architecture 200 includes a Tx buffer 220 receiving a first signal 202, a channel resistance 222, a communication channel 224 for the first signal, and an Rx buffer 226.

The XTC architecture 200 further includes a Tx buffer 228 receiving a second signal 204, a channel resistance 230, a communication channel 232 for the second signal, and an Rx buffer 234.

XTC architecture 200 may be associated with FEXT 236 between communication channels 224 and 232. In some aspects, a PeXTC circuit 206 can be used to mitigate the FEXT 236.

In some aspects, the PeXTC circuit 206 includes a buffer 214, channel resistance 216, a capacitor 218, and a transistor 242, coupling the second signal 204 with the communication channel 224 of the first signal 202. The PeXTC circuit 206 further includes a buffer 208, channel resistance 210, a capacitor 212, and a transistor 240, coupling the first signal 202 with the communication channel 232 of the second signal 204.

In some aspects, the PeXTC circuit 206 further includes a pattern sensor 238 (also referred to as a pattern-aware logic or XTC PAW logic). The pattern sensor 238 receives the first signal 202 and the second signal 204 and determines the switching pattern for each of the first signal 202 and the second signal 204. The PeXTC circuit 206 generates an enable signal 244 based on the determined switching pattern. For example, PeXTC circuit 206 generates the enable signal 244 when the first signal 202 and the second signal 204 switch in the same direction (e.g., both signals are associated with an even mode switching pattern, such as the even mode switching pattern illustrated in FIG. 8). In some aspects, the enable signal 244 is used to enable (or turn ON) transistors 242 and/or 240 (which act as switches) to allow communication of the signal output from capacitors 218 and 212 to be injected into the corresponding communication channels 224 and/or 232 to perform XTC and mitigate FEXT 236.

A more detailed diagram of a PeXTC circuit used in an XTC architecture is discussed in connection with FIG. 3.

FIG. 3 illustrates a high-level block diagram of a Tx side pattern-aware enhanced XTC (PeXTC) architecture, in accordance with some embodiments.

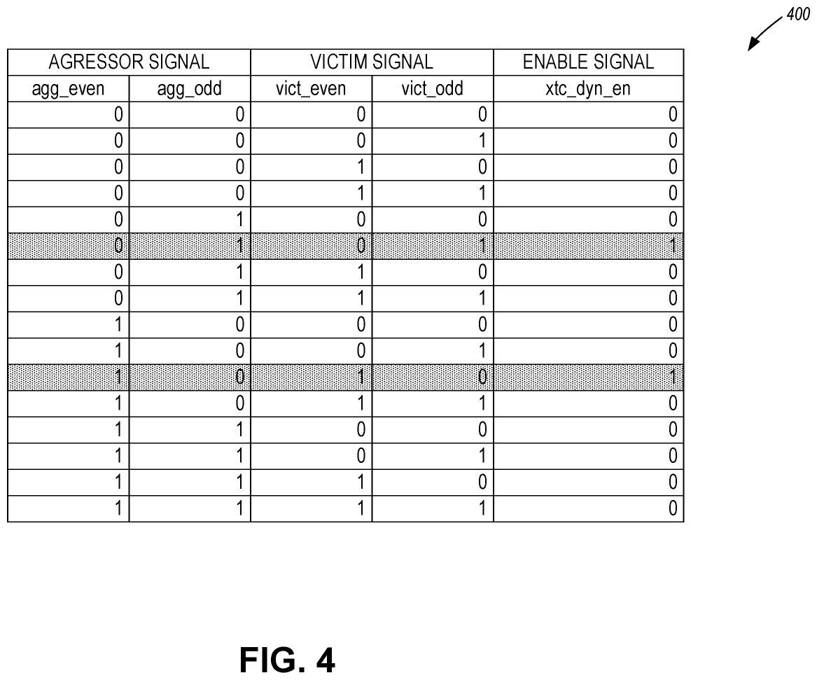

FIG. 4 illustrates a truth table 400 that can be used by the PeXTC architecture of FIG. 3, in accordance with some embodiments.

Referring to FIG. 3, the XTC architecture 300 includes a Tx driver 308 receiving a first signal 366 (also referred to as the victim signal), which can be a serialized signal. More specifically, flip-flop circuit 302 outputs an even signal 362, and flip-flop circuit 304 outputs an odd signal 364. The even signal 362 and odd signal 364 are serialized by serializer 306 to generate a serialized signal (e.g., the first signal 366).

The XTC architecture 300 further includes a Tx driver 316 receiving a second signal 360 (also referred to as the aggressor signal), which can be a serialized signal. More specifically, flip-flop circuit 310 outputs an even signal 356, and flip-flop circuit 312 outputs an odd signal 358. The even signal 356 and the odd signal 358 are serialized by serializer 314 to generate a serialized signal (e.g., the second signal 360).

In some aspects, FEXT can exist between the communication channels of the first signal 366 and the second signal 360. The PeXTC circuit 301 can be used to mitigate FEXT using the XTC PAW logic 318 and XTC circuits 326, . . . , 328.

The XTC PAW logic 318 includes logical AND gates 320 and 322 coupled to a logical OR gate 324. The logical AND gates 320 and 322 receive as inputs signal sets 368 and 370, respectively, which can indicate the switching status of even signal 362 (or vic_even), odd signal 364 (or vic_odd), even signal 356 (or agg_even), odd signal 358 (or agg_odd), as well as the corresponding bar (or opposite) signals (namely, vic_oddb, agg_oddb, vic_evenb, and agg_evenb). In some aspects, signal sets 368 and 370 are configured in a truth table, such as truth table 400, illustrated in FIG. 4). In some aspects, the truth table can be stored at the PeXTC circuit 301.

The output of the logical AND gates 320 and 322 are communicated as inputs to the logical OR gate 324, which generates the enable signal 372 (also referred to as a dynamic enable signal) communicated as input to XTC circuits 326, . . . 328. In some aspects, the enable signal 372 is generated when the first signal 366 and the second signal 360 switch in the same direction (e.g., the two highlighted entries in truth table 400 of FIG. 4). In this regard, enable signal 372 can be indicative of the presence of an even mode switching pattern between the victim and aggressor signals, which can activate one or more of the XTC circuits 326, . . . , 328.

XTC circuit 326 includes a logical AND gate 330, an inverter 332, buffers 334 and 344 serially coupled, and driving a capacitor 354. An output of capacitor 354 is coupled to the signal channel of the first signal 366. In some aspects, buffers 334 and 344 are configured as tri-state inverters. For example, buffer 334 includes p-channel metal-oxide-semiconductor (PMOS) transistors 336 and 338 and n-channel metal-oxide-semiconductor (NMOS) transistors 340 and 342. Similarly, buffer 344 includes PMOS transistors 346 and 348 and NMOS transistors 350 and 352. Buffers 334 and 344 receive as input the aggressor signal (e.g., second signal 360).

In operation, the XTC PAW logic 318 receives signal sets 368 and 370 and generates the enable signal 372 when an even mode switching pattern between the victim and aggressor signals is detected. The enable signal 372 is communicated as input to the logical AND gate 330, which also receives the XTC gain signal 374 as a second input. The XTC gain signal 374 can be used to adjust the amount of gain desired for the XTC by activating (or selecting) one or more of the XTC circuits 326, . . . , 328. The output signal 331 from the logical AND gate 330 is used to activate buffers 334 and 344 to inject the output signal 374 generated by the capacitor 354 into the communication channel of the first signal 366 to achieve XTC during an even mode switching pattern between the victim and aggressor signals.

Even though the PeXTC circuit 301 is illustrated in FIG. 3 to include the XTC PAW logic 318 and the XTC circuits 326, . . . , 328, the disclosure is not limited in this regard, and a different level of circuit integration can be used. For example, one or more of the circuits illustrated in FIG. 3 can be stand-alone circuits, or two or more of the illustrated circuits can be implemented together (e.g., implemented as a single circuit (e.g., a single processor)).

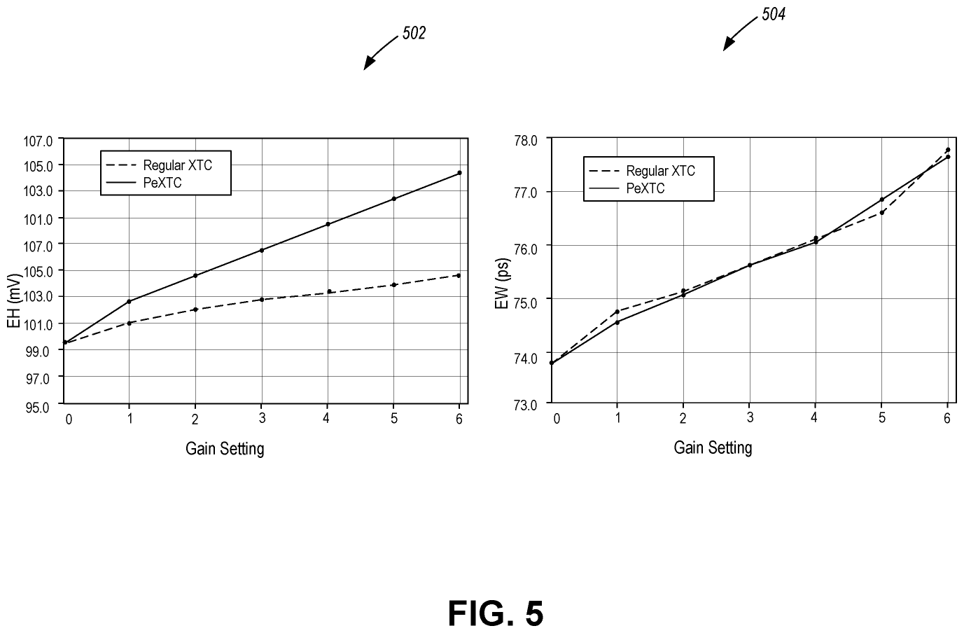

FIG. 5 illustrates graphs 502 and 504 showing improvement in margin with XTC gain in a regular XTC versus a PeXTC for a memory channel, in accordance with some embodiments. The disclosed circuit simulation data in FIG. 5 illustrates the XTC gain using the disclosed techniques. The analysis is done with a DDR5 channel model. FIG. 5 shows that with the increase in XTC gain of XTC circuits, there is no significant gain with regular XTC, while a significant improvement in Eye Height is observed with the disclosed PeXTC circuit.

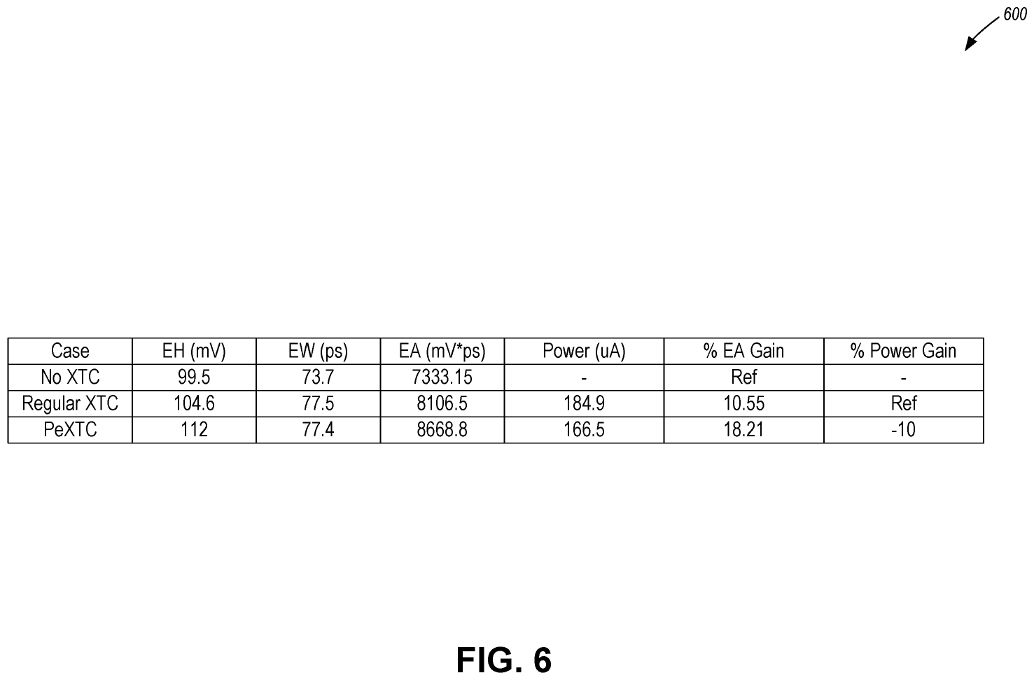

FIG. 6 illustrates table 600 showing improvement with a regular XTC and PeXTC for a memory channel in accordance with some embodiments. More specifically, table 600 shows the margins for the case with XTC gain=6. Table 600 shows a reduction in XTC power consumption by approximately 10% with respect to regular XTC. Also, as can be seen in FIG. 6, the Eye Area is improved by 18% by using the disclosed PeXTC circuit compared to 10% in regular XTC.

In some aspects, the pattern detector (e.g., the XTC PAW logic 318) can be upstream (before serializers 306 and 314) to provide more processing time. A 0-latency processing may not be a requirement. In some aspects, if needed, an additional delay can be provided using buffers for either the XTC or the signal path. In some aspects, a programmable delay element may be added to the XTC path to optimize the XTC further.

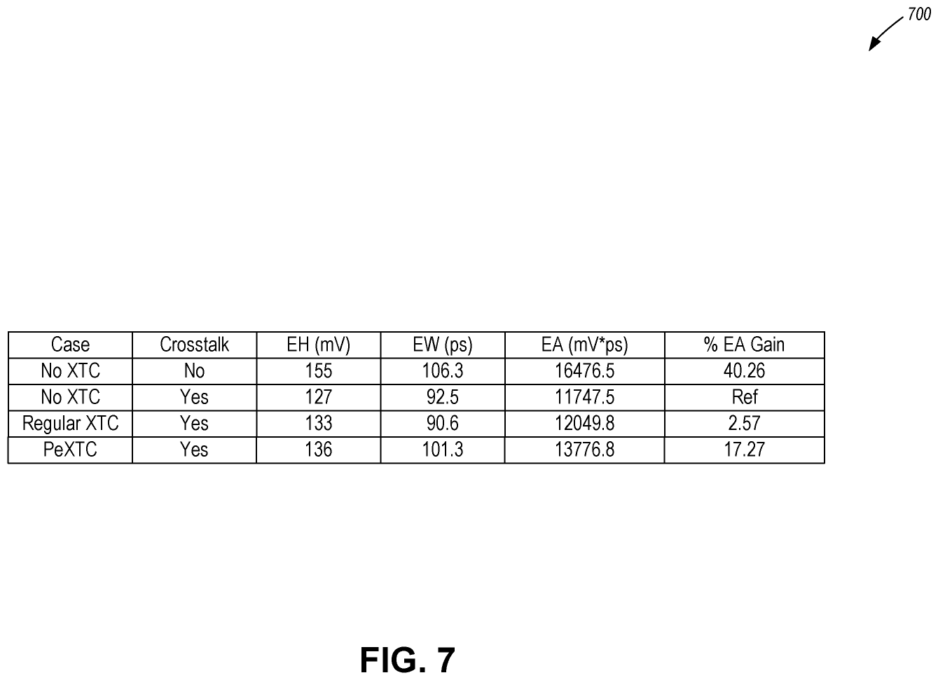

FIG. 7 illustrates table 700 showing improvement with a regular XTC and PeXTC for another memory channel, in accordance with some embodiments.

Channel transient simulation can be performed for the disclosed techniques using an LPDDR5 channel. Transmitter XTC analysis can be performed in this case. The circuit used may not be created in ADS, similar to the one shown in FIG. 3. Table 700 shows the margins with XTC. The delay of XTC aggressor input and XTC enable input can be optimized to obtain optimized results. As can be seen in Table 700, Eye Area improved by 17% when using PeXTC compared to 2% in regular XTC.

FIG. 8 illustrates graphs 802 and 804 of victim line modulation due to cross-talk aggressor pattern dependency, in accordance with some embodiments.

FIG. 9 illustrates graph 900 of the victim pattern with aggressor impact (e.g., high-side slice from FIG. 8) in accordance with some embodiments.

Cross-talk can be a significant limiter in a dense parallel bus (e.g., a memory interface) while enabling a higher data rate. Cross-talk from the aggressor bits could be either destructive or constructive. A destructive crosstalk will reduce the victim margin, while a constructive crosstalk will improve the victim margin. This is shown in FIG. 8. Graph 802 shows the victim and aggressor input pattern, and graph 804 shows the victim output signal modulated with cross-talk. A zoomed-in version of victim lines is also shown in graph 900 in FIG. 9. Most of the memory channels are dominated by inductively coupled cross-talk, and such a channel is considered for the disclosed study results below. On a platform with higher inductive cross-talk, even mode victim-aggressor patterns will result in destructive cross-talk, while an odd mode victim-aggressor pattern results in constructive pattern.

### (A) PoC: Case Study 1.

The analysis is done with 2 nets, one victim and another aggressor. The channel is excited with a worst-case ISI-Cross talk pattern derived from PDA analysis using a random stream of odd-even pattern combinations. The focus is to check the impact of regular XTC circuits and compare them against the disclosed pattern-aware enhanced XTC circuit. LPDDR5×2-Rank channel and Simple Rx side XTC circuit are used for analysis.

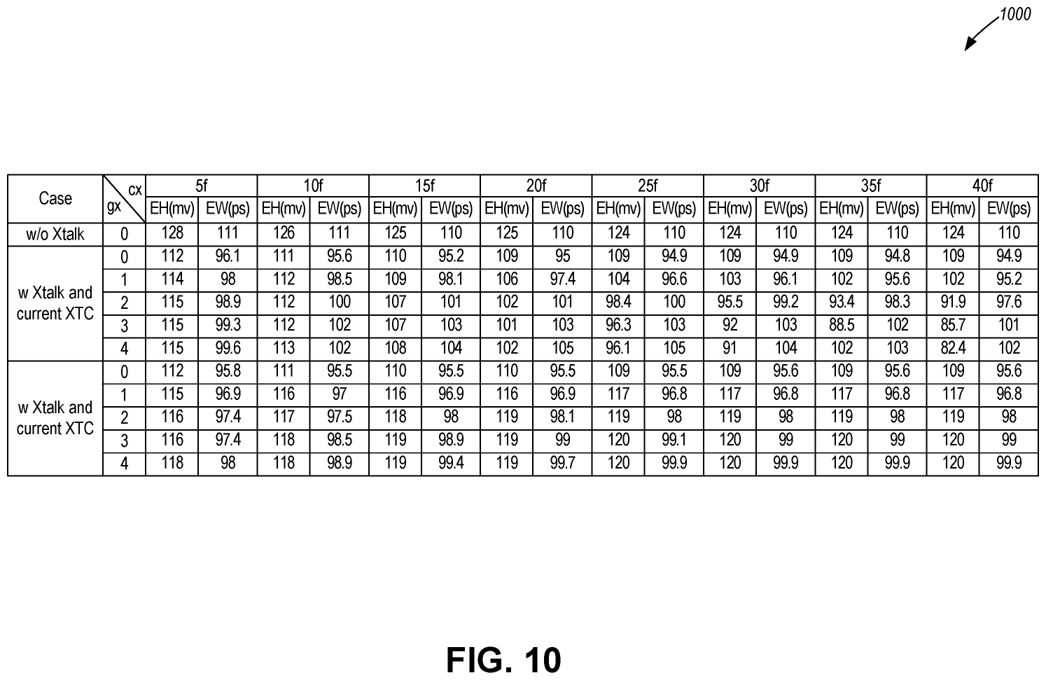

FIG. 10 illustrates table 1000 with XTC gain delay sweep (e.g., current XTC techniques versus disclosed PeXTC techniques), in accordance with some embodiments.

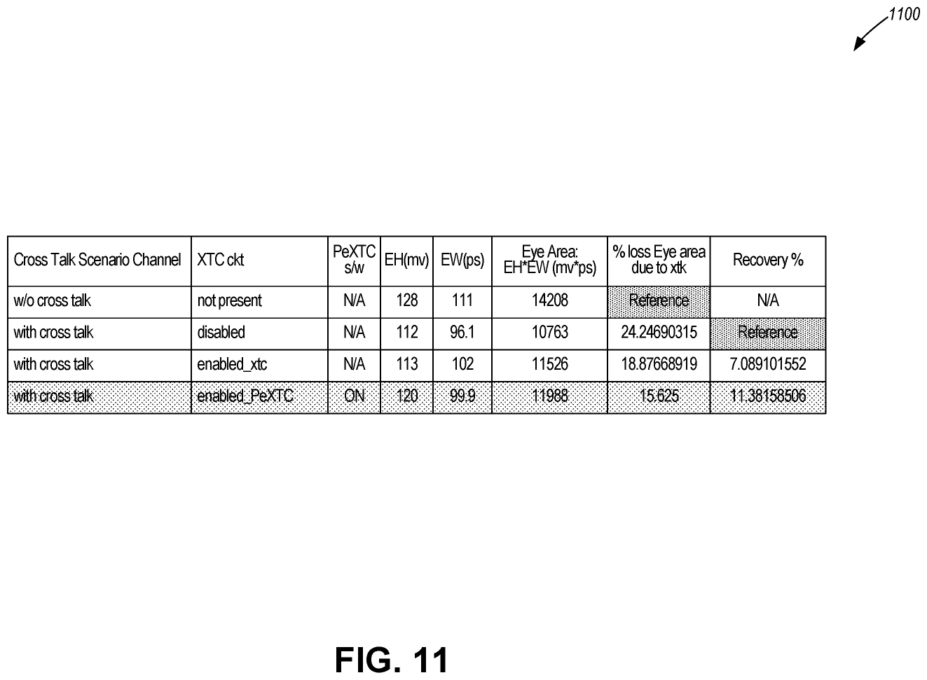

FIG. 11 illustrates table 1100 with a summary of best-case margins comparison and circuit effectiveness, in accordance with some embodiments;

Table 1000 shows the impact of tuning the parameters of a regular XTC circuit and a pattern-aware XTC circuit. Parameters gx and cx are the gain and delay of the XTC circuit swept to mimic the possible training scenarios. gx=0 implies that the XTC circuit is disabled. Table 1000 summarizes the optimal cases for all the tuning ranges. As can be seen from Table 1000, there is 1 mV/5.9 ps improvement with the current cancellation circuit, while margins improve by 8 mV/4.1 ps with a pattern-aware XTC circuit.

The best-case margins are summarized in Table 1100. Here, without cross-talk signifies an ISI-only scenario—the channel is not stressed with cross-talk. With cross-talk but cross-talk disable scenario indicates cross-talk is present in the channel, but the XTC circuit is turned OFF by gain control. The XTC circuit is still present but could overload the victim signal path. The XTC-enabled case is after turning on the regular XTC circuit. A PeXTC enabled indicates introducing the proposed pattern aware enhanced cross talk cancellation circuit. % eye area impact is an excellent matrix to compare the circuit effectiveness

### (B) POC Case Study 2.

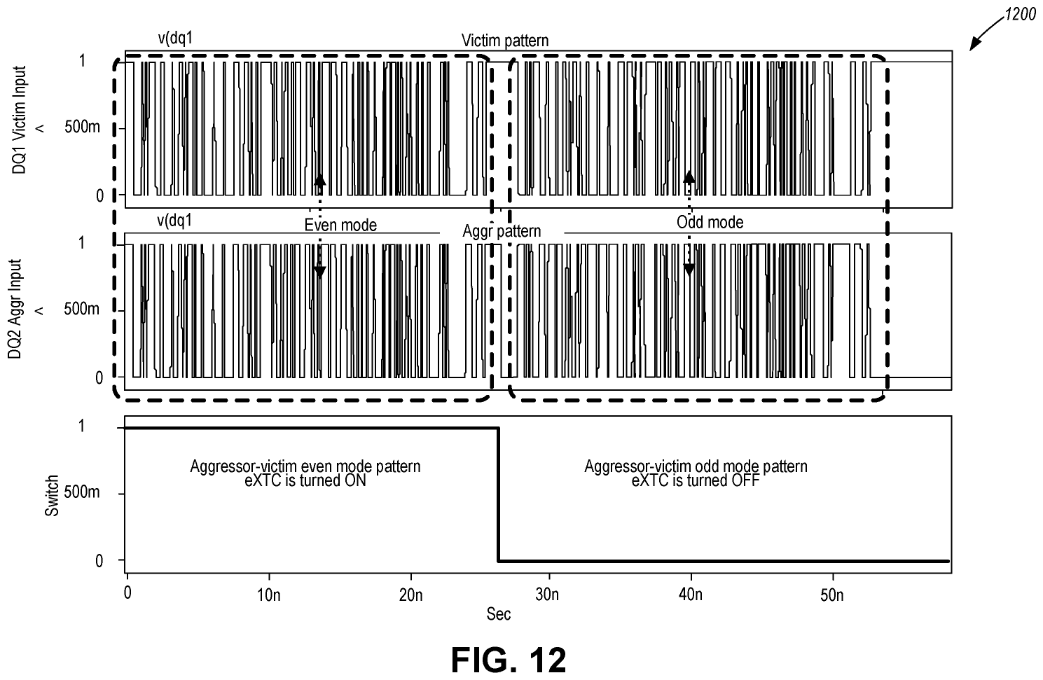

FIG. 12 illustrates graph 1200 of two sequential bursts of random even mode and odd mode victim-aggressor patterns, in accordance with some embodiments;

Analysis is done with 2 nets, considering one as the victim and the other as the aggressor. Channel is excited with random pattern in burst to check the impact of XTC circuit and then the impact of implementing pattern aware XTC circuit. In the burst of transmission, the aggressor has the same transition as the victim (even mode excitation). In contrast, in the second burst, the aggressor has the opposite transition as the victim (odd mode excitation). This is shown in FIG. 12. The LPDDR5× channel is used with a simplified Rx side cross-talk cancellation circuit used for analysis.

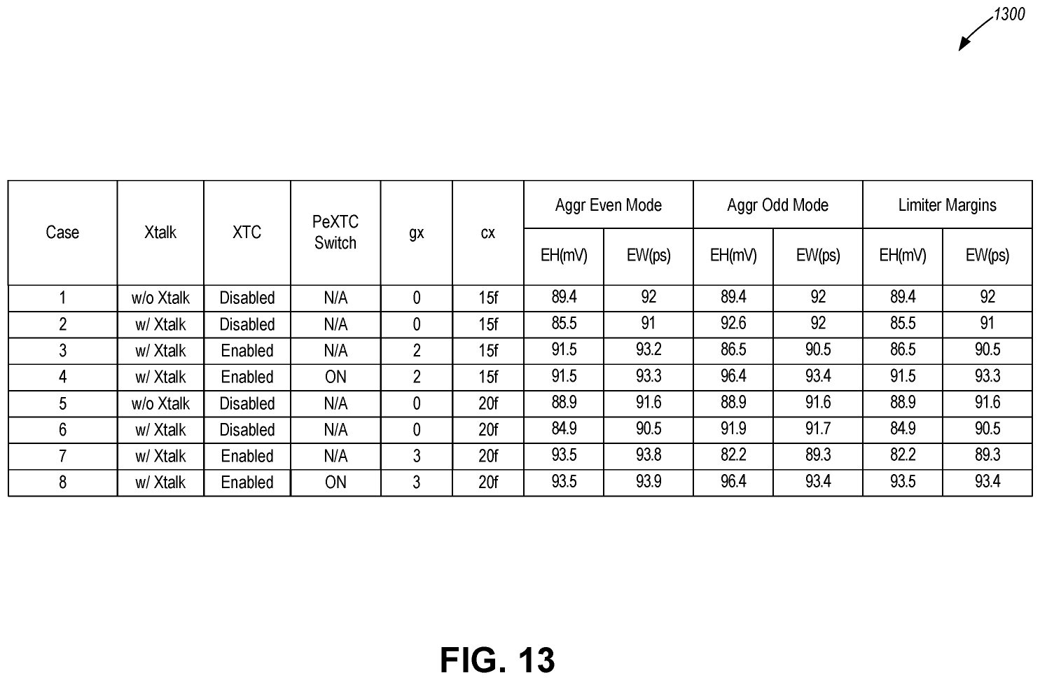

FIG. 13 illustrates table 1300 with regular XTC circuit parameter sweeps and impact with odd mode and even mode aggression, in accordance with some embodiments.

Table 1300 shows the impact of the XTC circuit on even mode and

odd mode aggressor patterns. The parameters gx and cx are the gain and delay of the XTC circuit. gx=0 implies that the XTC circuit is disabled. The following observations can be made from the analysis:

(a) Comparison of [Case #2 vs. Case #1] indicates even mode aggressor hurts the ISI margin, but odd mode cross-talk can gain the margin if the channel is dominated with inductive coupling.

(b) Comparison of both [Case #2 vs. Case #3] and [Case #6 vs. Case #7] shows that a regular XTC scheme partially regains the margin loss from the even mode aggressor while the circuit kills the crosstalk gain from odd mode aggressor.

(c) Comparison of both [Case #3 vs. Case #4] and [Case #7 vs. Case #8] indicates that pattern-aware enhanced XTC scheme practically regains the margin loss from even mode aggressor while retaining the crosstalk gain from odd mode aggressor.

(d) Case #3 and Case #7 show that margins with odd mode aggressor patterns become a limiter in overall margin calculation and need to be improved. Case #7 specifically suggests that the effectiveness of the regular XTC circuit is highly constrained due to odd mode impact in an inductively coupled channel.

(e) Case #4 and Case #8 show that margins with pattern-aware XTC are better than the current XTC circuit. Case #8 suggests explicitly that a pattern-aware XTC scheme frees up the opportunity to improve the crosstalk cancellation gain with more comprehensive gx/cx ranges compared to regular XTC.

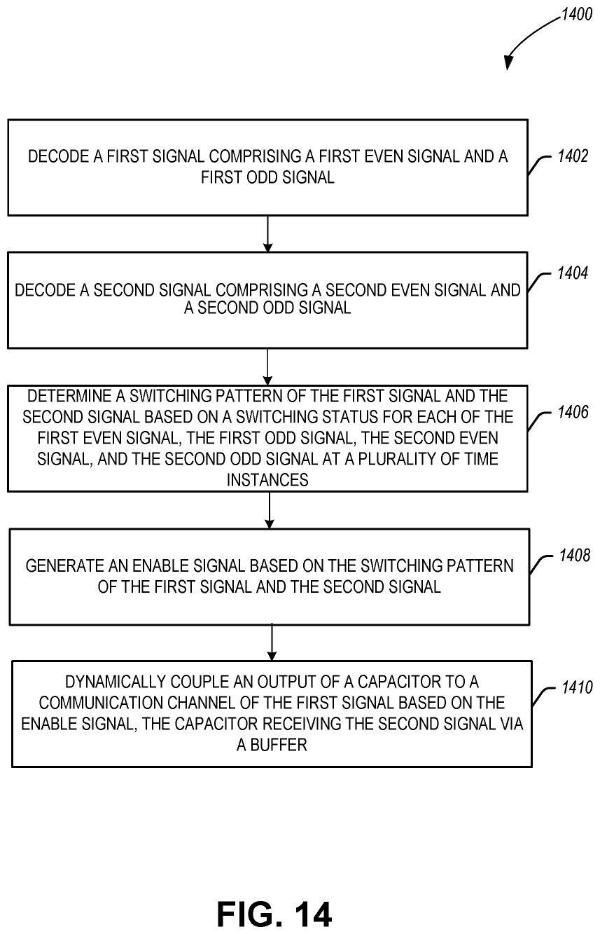

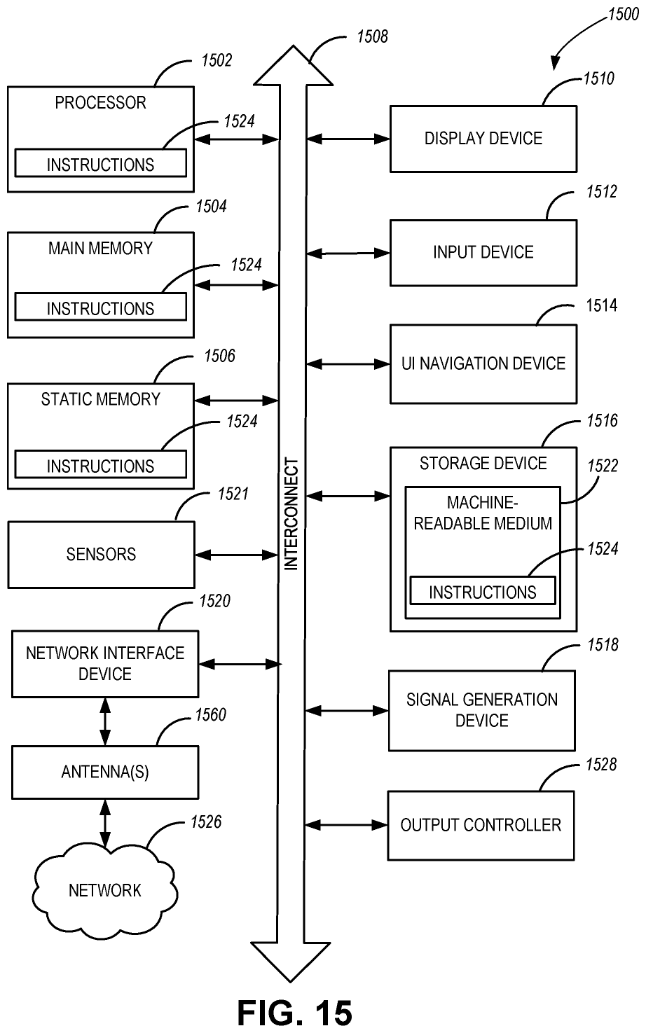

FIG. 14 is a flow diagram of an example method 1400 for XTC, in accordance with some embodiments. Referring to FIG. 14, method 1400 includes operations 1402, 1404, 1406, 1408, and 1410, which may be executed by a PeXTC circuit (e.g., PeXTC circuit 301 of FIG. 3) or another processor of a computing device (e.g., hardware processor 1502 of machine 1500 illustrated in FIG. 15, which can include one or more of the circuits illustrated in FIG. 3). In some embodiments, one or more of the circuits illustrated in FIG. 3 can perform the functionalities discussed in FIG. 14 as well as in the examples listed below.

At operation 1402, a first signal (e.g., first signal 366) is decoded, where the first signal includes a first even signal (e.g., even signal 362) and a first odd signal (e.g., odd signal 364).

At operation 1404, a second signal (e.g., second signal 360) is decoded, where the second signal includes a second even signal (e.g., even signal 356) and a second odd signal (e.g., odd signal 358).

At operation 1406, a switching pattern of the first signal and the second signal is determined based on a switching status for each of the first even signal, the first odd signal, the second even signal, and the second odd signal at a plurality of time instances. For example, the switching status for each of the signal sets 368 and 370 can be determined based on the truth table 400 of FIG. 4.

At operation 1408, an enable signal (e.g., enable signal 372) is generated based on the switching pattern of the first signal and the second signal (e.g., when an even mode switching pattern is detected).

At operation 1410, an output of a capacitor (e.g., capacitor 354) can be dynamically coupled (e.g., the capacitor can be dynamically activated or switched) to a communication channel of the first signal based on the enable signal. The capacitor (e.g., capacitor 354) receives the second signal (e.g., second signal 360) via a buffer (e.g., buffers 334 and 344).

FIG. 15 illustrates a block diagram of an example machine 1500 upon which any one or more of the techniques (e.g., methodologies) discussed herein may perform. In alternative embodiments, the machine 1500 may operate as a standalone device or may be connected (e.g., networked) to other machines. In a networked deployment, machine 1500 may operate in the capacity of a server machine, a client machine, or both in server-client network environments. In an example, machine 1500 may function as a peer machine in a peer-to-peer (P2P) (or other distributed) network environment. The machine 1500 may be a personal computer (PC), a tablet PC, a set-top box (STB), a personal digital assistant (PDA), a portable communications device, a mobile telephone, a smartphone, a web appliance, a network router, switch or bridge, or any other computing device capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations. The terms “machine,” “computing device,” and “computer system” are used interchangeably.

Machine (e.g., computer system) 1500 may include a hardware processor 1502 (e.g., a central processing unit (CPU), a graphics processing unit (GPU), a hardware processor core, or any combination thereof), a main memory 1504, and a static memory 1506, some or all of which may communicate with each other via an interlink 1508 (e.g., a bus). In some aspects, the main memory 1504, the static memory 1506, or any other type of memory (including cache memory) used by machine 1500 can be configured based on the disclosed techniques or can implement the disclosed memory devices.

Specific examples of main memory 1504 include Random Access Memory (RAM) and semiconductor memory devices, which may include, in some embodiments, storage locations in semiconductors such as registers. Specific examples of static memory 1506 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; and CD-ROM and DVD-ROM disks.

Machine 1500 may further include a display device 1510, an input device 1512 (e.g., a keyboard), and a user interface (UI) navigation device 1514 (e.g., a mouse). In an example, the display device 1510, input device 1512, and UI navigation device 1514 may be a touch screen display. The machine 1500 may additionally include a storage device (e.g., drive unit or another mass storage device) 1516, a signal generation device 1518 (e.g., a speaker), a network interface device 1520, and one or more sensors 1521, such as a global positioning system (GPS) sensor, compass, accelerometer, or other sensors. The machine 1500 may include an output controller 1528, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). In some embodiments, the hardware processor 1502 and/or instructions 1524 may comprise processing circuitry and/or transceiver circuitry.

The storage device 1516 may include a machine-readable medium 1522 on which one or more sets of data structures or instructions 1524 (e.g., software) embodying or utilized by any one or more of the techniques or functions described herein can be stored. Instructions 1524 may also reside, completely or at least partially, within the main memory 1504, within static memory 1506, or the hardware processor 1502 during execution thereof by the machine 1500. In an example, one or any combination of the hardware processor 1502, the main memory 1504, the static memory 1506, or the storage device 1516 may constitute machine-readable media.

Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

While the machine-readable medium 1522 is illustrated as a single medium, the term “machine-readable medium” may include a single medium or multiple media (e.g., a centralized or distributed database and/or associated caches and servers) configured to store instructions 1524.

An apparatus of the machine 1500 may be one or more of a hardware processor 1502 (e.g., a central processing unit (CPU), a graphics processing unit (GPU), a hardware processor core, or any combination thereof), a main memory 1504 and a static memory 1506, one or more sensors 1521, a network interface device 1520, one or more antennas 1560, a display device 1510, an input device 1512, a UI navigation device 1514, a storage device 1516, instructions 1524, a signal generation device 1518, and an output controller 1528. The apparatus may be configured to perform one or more of the methods and/or operations disclosed herein. The apparatus may be intended as a component of machine 1500 to perform one or more of the methods and/or operations disclosed herein and/or to perform a portion of one or more of the methods and/or operations disclosed herein. In some embodiments, the apparatus may include a pin or other means to receive power. In some embodiments, the apparatus may include power conditioning hardware.

The term “machine-readable medium” may include any medium that is capable of storing, encoding, or carrying instructions for execution by machine 1500 and that causes machine 1500 to perform any one or more of the techniques of the present disclosure or that is capable of storing, encoding, or carrying data structures used by or associated with such instructions. Non-limiting machine-readable medium examples may include solid-state memories and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks. In some examples, machine-readable media may include non-transitory machine-readable media. In some examples, machine-readable media may include machine-readable media that is not a transitory propagating signal.

The instructions 1524 may further be transmitted or received over a communications network 1526 using a transmission medium via the network interface device 1520 utilizing any one of several transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, a Long Term Evolution (LTE) family of standards, a Universal Mobile Telecommunications System (UMTS) family of standards, peer-to-peer (P2P) networks, among others.

In an example, the network interface device 1520 may include one or more physical jacks (e.g., Ethernet, coaxial, or phone jacks) or one or more antennas to connect to the communications network 1526. In an example, the network interface device 1520 may include one or more antennas 1560 to wirelessly communicate using at least one single-input multiple-output (SIMO), multiple-input multiple-output (MIMO), or multiple-input single-output (MISO) techniques. In some examples, the network interface device 1520 may wirelessly communicate using multiple-user MIMO techniques. The term “transmission medium” shall be taken to include any intangible medium that can store, encode, or carry instructions for execution by the machine 1500 and includes digital or analog communications signals or other intangible media to facilitate communication of such software.

Examples, as described herein, may include, or may operate on, logic or several components, modules, or mechanisms. Modules are tangible entities (e.g., hardware) capable of performing specified operations and may be configured or arranged in a particular manner. In an example, circuits may be arranged (e.g., internally or concerning external entities such as other circuits) in a specified manner as a module. In an example, the whole or part of one or more computer systems (e.g., a standalone, client, or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part, all, or any operation described herein. Considering examples in which modules are temporarily configured, each of the modules need not be instantiated at any one moment in time. For example, where the modules comprise a general-purpose hardware processor configured using the software, the general-purpose hardware processor may be configured as respective different modules at separate times. The software may accordingly configure a hardware processor, for example, to constitute a particular module at one instance of time and to constitute a different module at a different instance of time.

Some embodiments may be implemented wholly or partially in software and/or firmware. This software and/or firmware may take the form of instructions contained in or on a non-transitory computer-readable storage medium. Those instructions may then be read and executed by one or more processors to enable the performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM), random access memory (RAM), magnetic disk storage media, optical storage media, flash memory, etc.

The above-detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof) or with respect to other examples (or one or more aspects thereof) shown or described herein.

Publications, patents, and patent documents referred to in this document are incorporated by reference herein in their entirety, as though individually incorporated by reference. In the event of inconsistent usage between this document and those documents so incorporated by reference, the usage in the incorporated reference(s) is supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended; that is, a system, device, article, or process that includes elements in addition to those listed after such a term in a claim are still deemed to fall within the scope of that claim. Moreover, in the following claims, the terms “first,” “second,” and “third,” etc., are used merely as labels and are not intended to suggest a numerical order for their objects.

The embodiments as described above may be implemented in various hardware configurations that may include a processor for executing instructions that perform the techniques described. Such instructions may be contained in a machine-readable medium such as a suitable storage medium or a memory or other processor-executable medium.

The embodiments as described herein may be implemented in several environments, such as part of a system on chip, a set of intercommunicating functional blocks, or similar. However, the scope of the disclosure is not limited in this respect.

Described implementations of the subject matter can include one or more features, alone or in combination, as illustrated below by way of examples.

Example 1 is an apparatus comprising: a signal pattern sensing circuit comprising a plurality of logical gates, the signal pattern sensing circuit receives a first signal and a second signal and generates an enable signal at an output of one of the plurality of logical gates based on a switching pattern of the first signal and the second signal; and a cross-talk cancellation (XTC) circuit comprising a buffer coupled to a capacitor, the capacitor receiving the second signal via the buffer, and the XTC circuit dynamically coupling an output of the capacitor to a communication channel of the first signal based on the enable signal.

In Example 2, the subject matter of Example 1 includes subject matter where the plurality of logical gates comprises a first logical AND gate and a second logical AND gate to receive a plurality of input signals based on the first signal and the second signal.

In Example 3, the subject matter of Example 2 includes subject matter where the first signal comprises a first even signal and a first odd signal, and wherein the second signal comprises a second even signal and a second odd signal.

In Example 4, the subject matter of Example 3 includes subject matter where the signal pattern sensing circuit is to generate the plurality of input signals based on a switching status of the first even signal, the first odd signal, the second even signal, and the second odd signal at a plurality of time instances.

In Example 5, the subject matter of Examples 2-4 includes subject matter where the one of the plurality of logical gates comprises a logical OR gate.

In Example 6, the subject matter of Example 5 includes subject matter where an output of the first logical AND gate and an output of the second logical AND gate are coupled to an input of the logical OR gate.

In Example 7, the subject matter of Example 6 includes subject matter where the logical OR gate generates the enable signal based on the output of the first logical AND gate and the output of the second logical AND gate.

In Example 8, the subject matter of Examples 1-7 includes subject matter where the signal pattern sensing circuit generates the enable signal when the first signal and the second signal switch in the same direction.

In Example 9, the subject matter of Examples 1-8 includes subject matter where the XTC circuit comprises a logical AND gate receiving the enable signal and a gain control signal.

In Example 10, the subject matter of Example 9 includes one or more additional XTC circuits coupled in parallel with the XTC circuit, wherein the gain control signal is to enable or disable the one or more additional XTC circuits.

In Example 11, the subject matter of Example 10 includes each of the one or more additional XTC circuits comprising an additional buffer coupled to an additional capacitor, wherein the additional capacitor receives the second signal via the additional buffer.

In Example 12, the subject matter of Example 11 includes subject matter where the one or more additional XTC circuits dynamically couple an output of the additional capacitor to the communication channel of the first signal based on the enable signal and the gain control signal.

In Example 13, the subject matter of Examples 9-12 includes subject matter where the buffer comprises at least two tri-state inverters coupled in parallel with each other and wherein the at least two tri-state inverters drive the capacitor.

In Example 14, the subject matter of Example 13 includes an inverter, wherein an output of the logical AND gate is coupled to an input of the inverter and n-channel metal-oxide-semiconductor (NMOS) transistors of the at least two tri-state inverters.

In Example 15, the subject matter of Example 14 includes subject matter where an output of the inverter is coupled to p-channel metal-oxide-semiconductor (PMOS) transistors of the at least two tri-state inverters.

In Example 16, the subject matter of Example 15 includes subject matter where the second signal comprises an even signal and an odd signal, and wherein the apparatus further comprises a serializer to generate a serialized signal using the even signal and the odd signal.

In Example 17, the subject matter of Example 16 includes subject matter where an output of the serializer is coupled to an input of one of the at least two tri-state inverters.

In Example 18, the subject matter of Example 17 includes subject matter where the serialized signal is communicated to gate terminals of an NMOS-PMOS transistor pair of the one of the at least two tri-state inverters.

In Example 19, the subject matter of Examples 1-18 includes one or more interconnects coupled to the signal pattern sensing circuit and the XTC circuit.

In Example 20, the subject matter of Examples 1-19 includes subject matter where the apparatus comprises a processor and wherein the processor includes the signal pattern sensing circuit and the XTC circuit.

In Example 21, the subject matter of Example 20 includes one or more interconnects coupling the signal pattern sensing circuit and the XTC circuit.

Example 22 is a system comprising memory and at least one processor coupled to the memory, the at least one processor to decode a first signal comprising a first even signal and a first odd signal; decode a second signal comprising a second even signal and a second odd signal; determine a switching pattern of the first signal and the second signal based on a switching status for each of the first even signal, the first odd signal, the second even signal, and the second odd signal at a plurality of time instances; generate an enable signal based on the switching pattern of the first signal and the second signal; and dynamically couple an output of a capacitor to a communication channel of the first signal based on the enable signal, the capacitor to receive the second signal via a buffer.

In Example 23, the subject matter of Example 22 includes subject matter where the at least one processor is to generate the enable signal at an output of a logical OR gate, the logical OR gate coupled to outputs of a first logical AND gate and a second logical AND gate receiving a plurality of input signal based on the first signal and the second signal.

In Example 24, the subject matter of Example 23 includes subject matter where the at least one processor is to generate the plurality of input signals based on the switching status of the first even signal, the first odd signal, the second even signal, and the second odd signal at the plurality of time instances.

In Example 25, the subject matter of Examples 22-24 includes subject matter where the at least one processor is to generate the enable signal when the switching pattern indicates the first signal and the second signal switch in the same direction.

Example 26 is a method comprising decoding a first signal comprising a first even signal and a first odd signal; decoding a second signal comprising a second even signal and a second odd signal; determining a switching pattern of the first signal and the second signal based on a switching status for each of the first even signal, the first odd signal, the second even signal, and the second odd signal at a plurality of time instances; generating an enable signal based on the switching pattern of the first signal and the second signal; and dynamically coupling an output of a capacitor to a communication channel of the first signal based on the enable signal, the capacitor receiving the second signal via a buffer.

In Example 27, the subject matter of Example 26 includes generating the enable signal at an output of a logical OR gate, the logical OR gate coupled to outputs of a first logical AND gate and a second logical AND gate receiving a plurality of input signal based on the first signal and the second signal.

In Example 28, the subject matter of Example 27 includes generating the plurality of input signals based on the switching status of the first even signal, the first odd signal, the second even signal, and the second odd signal at the plurality of time instances.

In Example 29, the subject matter of Examples 26-28 includes generating the enable signal when the switching pattern indicates the first signal and the second signal switch in the same direction.

Example 30 is an apparatus comprising a first transmit (Tx) driver comprising an input terminal and an output terminal; a first tri-state inverter serially coupled to a second tri-state inverter; a first capacitor, wherein an input of the first capacitor is coupled to an output of the second tri-state inverter, and an output of the first capacitor is coupled to the output terminal of the first Tx driver; and a logical AND gate, wherein an output of the logical AND gate is coupled to an input of the first tri-state inverter.

In Example 31, the subject matter of Example 30 includes a second Tx driver comprising an input terminal and an output terminal, wherein the input terminal of the second Tx driver is coupled to an input of the first tri-state inverter.

In Example 32, the subject matter of Examples 30-31 includes a third tri-state inverter serially coupled to a fourth tri-state inverter and a second capacitor, wherein an input of the second capacitor is coupled to an output of the fourth tri-state inverter, and an output of the second capacitor is coupled to the output terminal of the first Tx driver.

In Example 33, the subject matter of Examples 30-32 includes a pattern-aware logic comprising a plurality of logical gates, wherein an output of the pattern-aware logic is coupled to an input of the first tri-state inverter.

In Example 34, the subject matter of Example 33 includes subject matter where the plurality of logical gates comprises at least two logical AND gates coupled to a logical OR gate and wherein an output of the logical OR gate is the output of the pattern-aware logic.

Example 35 is an apparatus comprising means to perform a method as Exampled in any preceding claim.

Example 36 is machine-readable storage including machine-readable instructions, which, when executed, causes a transceiver to implement a method as shown in any preceding claim.

Example 37 is machine-readable storage including machine-readable instructions, which, when executed, causes an equalization circuit to implement a method as shown in any preceding claim.

Example 38 is a computer program comprising instructions which, when a computer executes the program, causes the computer to carry out the method as Exampled in any preceding claim.

Example 39 is at least one machine-readable medium including instructions that, when executed by processing circuitry, cause the processing circuitry to perform operations to implement any of Examples 1-38.

Example 40 is an apparatus comprising means to implement any of Examples 1-38.

Example 41 is a system to implement any of Examples 1-38.

Example 42 is a method to implement any of Examples 1-38.

The above description is intended to be illustrative and not restrictive. For example, the above-described examples (or one or more aspects thereof) may be used in combination with others. Other embodiments may be used, such as by one of ordinary skill in the art upon reviewing the above description. The Abstract is to allow the reader to ascertain the nature of the technical disclosure quickly. It is submitted with the understanding that it will not be used to interpret or limit the scope or meaning of the claims. Also, in the above Detailed Description, various features may be grouped to streamline the disclosure. However, the claims may not set forth every feature disclosed herein as embodiments may feature a subset of said features. Further, embodiments may include fewer features than those disclosed in a particular example. Thus, the following claims are now incorporated into the Detailed Description, with a claim standing on its own as a separate embodiment. The scope of the embodiments disclosed herein is to be determined regarding the appended claims, along with the full scope of equivalents to which such claims are entitled.

What is claimed is:

1. An apparatus comprising:
a signal pattern sensing circuit comprising a plurality of logical gates, the signal pattern sensing circuit receives a first signal and a second signal and generates an enable signal at an output of one of the plurality of logical gates based on a switching pattern of the first signal and the second signal; and
a cross-talk cancellation (XTC) circuit comprising a buffer coupled to a capacitor, the capacitor receiving the second signal via the buffer, and the XTC circuit dynamically coupling an output of the capacitor to a communication channel of the first signal based on the enable signal.

2. The apparatus of claim 1, wherein the plurality of logical gates comprises a first logical AND gate and a second logical AND gate to receive a plurality of input signal based on the first signal and the second signal.

3. The apparatus of claim 2, wherein the first signal comprises a first even signal and a first odd signal, and wherein the second signal comprises a second even signal and a second odd signal.

4. The apparatus of claim 3, wherein the signal pattern sensing circuit is to generate the plurality of input signals based on a switching status of the first even signal, the first odd signal, the second even signal, and the second odd signal at a plurality of time instances.

5. The apparatus of claim 2, wherein the one of the plurality of logical gates comprises a logical OR gate.

6. The apparatus of claim 5, wherein an output of the first logical AND gate and an output of the second logical AND gate are coupled to an input of the logical OR gate.

7. The apparatus of claim 6, wherein the logical OR gate generates the enable signal based on the output of the first logical AND gate and the output of the second logical AND gate.

8. The apparatus of claim 1, wherein the signal pattern sensing circuit generates the enable signal when the first signal and the second signal switch in the same direction.

9. The apparatus of claim 1, wherein the XTC circuit comprises a logical AND gate receiving the enable signal and a gain control signal.

10. The apparatus of claim 9, further comprising one or more additional XTC circuits coupled in parallel with the XTC circuit, wherein the gain control signal is to enable or disable the one or more additional XTC circuits, wherein each of the one or more additional XTC circuits comprising an additional buffer coupled to an additional capacitor, and wherein the additional capacitor receives the second signal via the additional buffer.

11. The apparatus of claim 10, wherein the one or more additional XTC circuits dynamically couple an output of the additional capacitor to the communication channel of the first signal based on the enable signal and the gain control signal.

12. A method comprising:
decoding a first signal comprising a first even signal and a first odd signal;
decoding a second signal comprising a second even signal and a second odd signal;
determining a switching pattern of the first signal and the second signal based on a switching status for each of the first even signal, the first odd signal, the second even signal, and the second odd signal at a plurality of time instances;
generating an enable signal based on the switching pattern of the first signal and the second signal; and
dynamically coupling an output of a capacitor to a communication channel of the first signal based on the enable signal, the capacitor receiving the second signal via a buffer.

13. The method of claim 12, further comprising:
generating the enable signal at an output of a logical OR gate, the logical OR gate coupled to outputs of a first logical AND gate and a second logical AND gate, the first logical AND gate and the second logical AND gate receiving a plurality of input signals based on the first signal and the second signal.

14. The method of claim 13, further comprising:
generating the plurality of input signals based on the switching status of the first even signal, the first odd signal, the second even signal, and the second odd signal at the plurality of time instances.

15. The method of claim 12, further comprising:
generating the enable signal when the switching pattern indicates the first signal and the second signal switch in the same direction.

16. An apparatus comprising:
a first transmit (Tx) driver comprising an input terminal and an output terminal;
a first tri-state inverter serially coupled to a second tri-state inverter;
a first capacitor, wherein an input of the first capacitor is coupled to an output of the second tri-state inverter, and an output of the first capacitor is coupled to the output terminal of the first Tx driver; and
a logical AND gate, wherein an output of the logical AND gate is coupled to an input of the first tri-state inverter.

17. The apparatus of claim 16, further comprising:
a second Tx driver comprising an input terminal and an output terminal, wherein the input terminal of the second Tx driver is coupled to an input of the first tri-state inverter.

18. The apparatus of claim 16, further comprising:
a third tri-state inverter serially coupled to a fourth tri-state inverter; and
a second capacitor, wherein an input of the second capacitor is coupled to an output of the fourth tri-state inverter, and an output of the second capacitor is coupled to the output terminal of the first Tx driver.

19. The apparatus of claim 16, further comprising:
a pattern-aware logic comprising a plurality of logical gates, wherein an output of the pattern-aware logic is coupled to an input of the first tri-state inverter.

20. The apparatus of claim 19, wherein the plurality of logical gates comprises at least two logical AND gates coupled to a logical OR gate, and wherein an output of the logical OR gate is the output of the pattern-aware logic.
